(19) United States
(12) Patent Application Publication
(10) Pub. No.: US 2025/0024652 A1
(43) Pub. Date: Jan. 16, 2025

(54) CONVERTER

(71) Applicant: LG INNOTEK CO., LTD., Seoul (KR)

(72) Inventors: Ki Dong KIM, Seoul (KR); Byung Nam CHOI, Seoul (KR)

(73) Assignee: LG INNOTEK CO., LTD., Seoul (KR)

(21) Appl. No.: 18/712,610

(22) PCT Filed: Dec. 14, 2022
(86) PCT No.: PCT/KR2022/020321

§ 371 Date: May 22, 2024

(30) Foreign Application Priority Data
Dec. 21, 2021 (KR) 10-2021-0184399

(51) Int. Cl. H05K 7/20; H05K 7/14

(52) U.S. Cl. CPC H05K 7/20927; H05K 7/1432

(57) ABSTRACT

A converter comprises: a housing; refrigerant pipes which are coupled to the housing and which each have an end portion protruding from the outer surface of the housing; and brackets coupled to the outer surfaces of the refrigerant pipes, wherein the bracket includes: a first body encompassing a portion of the outer surface of the refrigerant pipe; and a second body which is hinge-coupled to the first body and which encompasses the other portion of the outer surface of the refrigerant pipe, and the first body or the second body includes a protruding part protruding from the outer surface thereof.

### TECHNICAL FIELD

The present embodiment relates to a converter.

### BACKGROUND ART

As electric devices of automobiles, engine electric devices (starting device, ignition device, and charging device) and lighting device are common, but in recent years, as vehicles are more electronically controlled, most systems including chassis electric devices are becoming electric and electronic.

Various electric components such as lamps, audio, heaters, and air conditioners being installed in automobiles receive power from the battery when the car is stopped and receive power from the generator when driving, and at this time, the power generation capacity of the 14V power system is used as a normal power supply voltage.

Recently, along with the development of the information technology industry, various new technologies (motorized power steering, Internet, and the like) for the purpose of increasing the convenience of automobiles are being adopted to vehicles, and in the future, it is expected that the development of new technologies that can utilize the current automobile system to the maximum will continue.

A hybrid electric vehicle (HEV), regardless of soft or hard type, is equipped with a DC-DC converter for supplying an electric load (12V). In addition, the DC-DC converter, which acts as a generator (alternator) of a general gasoline vehicle, supplies a voltage of 12V for the electric load by reducing the high voltage of the main battery (usually a high-voltage battery of 144V or more).

A DC-DC converter refers to an electronic circuit device that converts DC power of a certain voltage to DC power of another voltage, and is used in various fields such as automobile electronic products and television sets.

An outer shape of a converter is formed by a housing. A plurality of electronic components is disposed inside the housing. Electronic components generate heat by being driven. Heat may cause overload of electronic components, causing a failure in a setting function and causing failure. Accordingly, the converter includes a refrigerant pipe for heat dissipation of the components. The refrigerant pipe includes a flow path through which the refrigerant flows, and a refrigerant inlet and a refrigerant outlet are formed at both ends, respectively.

Accordingly, a refrigerant supply unit for providing a refrigerant through a flow path and a refrigerant recovery unit for recovering the refrigerant flowing through the flow path are coupled to both ends of the refrigerant pipe. A structure for preventing arbitrary rotation is required in connection between a refrigerant supply unit and a refrigerant inlet, a refrigerant outlet and a refrigerant recovery unit, that is, different components.

### DETAILED DESCRIPTION OF THE INVENTION

### Technical Subject

The present embodiment is intended to provide a converter capable of being firmly coupled to each other by preventing arbitrary rotation between a refrigerant pipe and components being coupled to the refrigerant pipe, thereby facilitating refrigerant inflow and discharge.

### Technical Solution

A converter according to the present embodiment comprises: a housing; a refrigerant pipe being coupled to the housing and having end portions being protruded from an outer surface of the housing; and a bracket being coupled to an outer surface of the refrigerant pipe, wherein the bracket includes: a first body encompassing a portion of an outer surface of the refrigerant pipe; and a second body being hinge-coupled to the first body and encompassing the other portion of an outer surface of the refrigerant pipe, and wherein the first body or the second body includes a protruding part being protruded from an outer surface thereof.

The first body includes: a first body part, in the shape of an arc, being coupled to an outer surface of the refrigerant pipe; and a first coupling part being disposed outside the first body part and coupled to an outer surface of the housing, wherein the protruding part may be disposed on an outer surface of the first body portion.

The second body includes: a second body part, in the shape of an arc, being coupled to an outer surface of the refrigerant pipe; and a second coupling part being disposed outside the second body part and coupled to an outer surface of the housing, wherein the protruding part may be disposed on an outer surface of the first body part.

The first body includes a first hinge part being disposed outside the first body part; the second body includes a second hinge part being disposed outside the second body part; and a hinge pin whose both ends are coupled to the first hinge part and the second hinge part may be included.

The protruding part includes: a first protruding part being disposed on an outer surface of the first body part; and a second protruding part being disposed on an outer surface of the second body part, wherein the first protruding part and the second protruding part may be disposed symmetrically about the refrigerant pipe.

The first coupling part includes a first hole penetrating from an inner surface to an outer surface; the housing includes a first screw hole facing the first hole; and a screw penetrating the first hole and being coupled to the first screw hole may be included.

The first coupling part may include a second hole penetrating from an inner surface to an outer surface, wherein the housing may include a rib being protruded from an outer surface and coupled to the second hole.

The second coupling part includes a third hole penetrating from the inner surface to the outer surface, wherein the housing includes a second screw hole facing the third hole, and wherein a screw penetrating the third hole and being coupled to the second screw hole may be included.

On an outer surface of the first coupling part, a step region in a shape being more recessed than other regions is included; the second coupling part is coupled to the step region and includes a third hole facing the first hole; and the screw may penetrate through the third hole and the first hole to be coupled to the first screw hole.

The refrigerant pipe may include a guide being formed to have a larger cross-sectional area than other regions, wherein the bracket may be disposed between the guide and an outer surface of the housing.

### Advantageous Effects

Through the present embodiment, a structure that prevents the rotation of the refrigerant pipe is implemented using a bracket so that there is an advantage in that the coupling between the refrigerant pipe and other components can be firmly maintained in a region where the refrigerant is supplied or recovered.

In addition, since a structure that prevents the rotation of the refrigerant pipe can be implemented with only a bracket regardless of the type of refrigerant pipe, there is an advantage in that the degree of freedom in design is increased.

### BRIEF DESCRIPTION OF DRAWINGS

FIG. 1 is a perspective view illustrating the appearance of a converter according to an embodiment of the present invention.

FIG. 2 is a plan view illustrating a side surface of a converter according to an embodiment of the present invention.

FIG. 3 is an exploded perspective view of a converter according to an embodiment of the present invention.

FIG. 4 is a perspective view of a bracket according to a first embodiment of the present invention.

FIG. 5 is a diagram for explaining the process of coupling a bracket and a refrigerant pipe according to a first embodiment of the present invention.

FIG. 6 is a perspective view of a bracket according to a second embodiment of the present invention.

FIG. 7 is a diagram for explaining the process of coupling a bracket and a refrigerant pipe according to a second embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and within the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or arranged in “on (above)” or “below (under)” of each component, “on (above)” or “below (under)” means that it includes not only the case where the two components are directly in contact with, but also the case where one or more other components are formed or arranged between the two components. In addition, when expressed as “on (above)” or “below (under)”, the meaning of not only an upward direction but also a downward direction based on one component may be included.

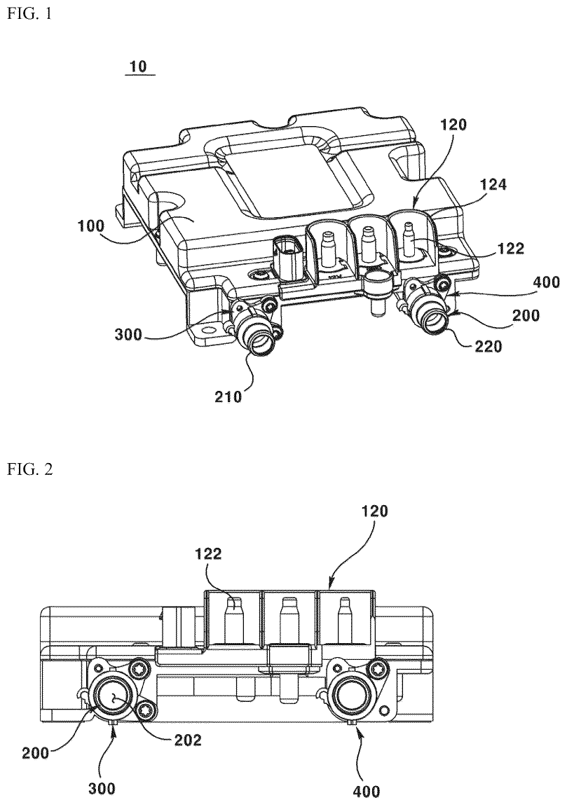

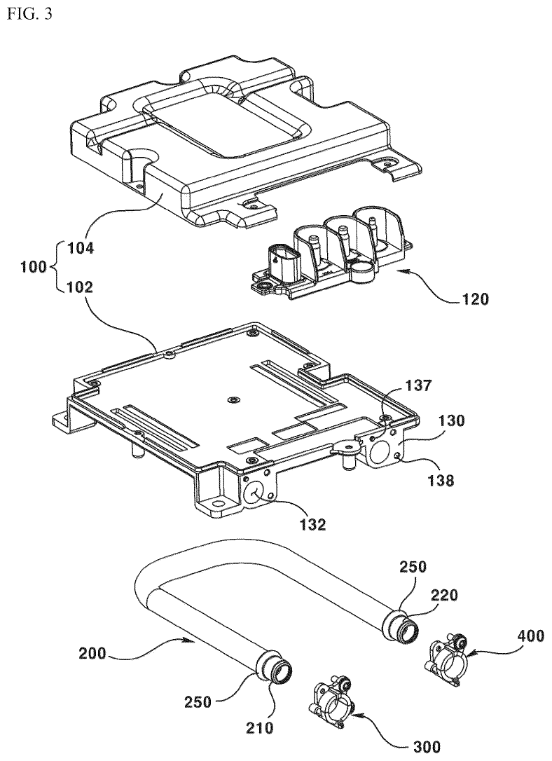

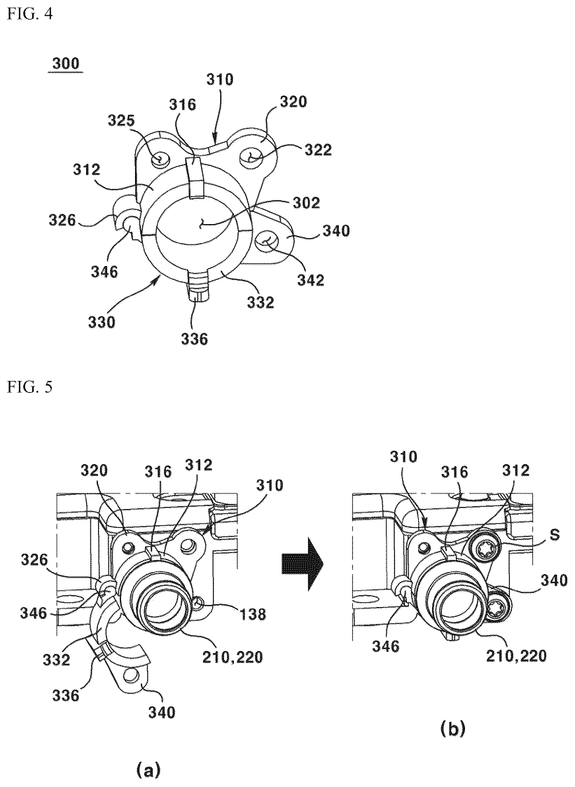

FIG. 1 is a perspective view illustrating the appearance of a converter according to an embodiment of the present invention; FIG. 2 is a plan view illustrating a side surface of a converter according to an embodiment of the present invention: FIG. 3 is an exploded perspective view of a converter according to an embodiment of the present invention; FIG. 4 is a perspective view of a bracket according to a first embodiment of the present invention; and FIG. 5 is a diagram for explaining the process of coupling a bracket and a refrigerant pipe according to a first embodiment of the present invention.

Referring to FIGS. 1 to 5, an external shape of a converter 10 according to a first embodiment of the present invention may be formed by the housing 100. The housing 100 may be made of metal or plastic. A space in which at least one component for driving the converter 10 is disposed may be formed inside the housing 100. The component may generate heat by being driven.

The housing 100 may include a main body 102 and a cover 104. The space may be formed between the main body 102 and the cover 104. The cover 104 may be disposed to cover the upper surface of the main body 102.

A connector 120 may be disposed on an outer surface of the housing 100. The connector 120 may be disposed on an upper surface of the housing 100. The cover 104 may include a groove so that the connector 120 is disposed. The connector 120 may include a plurality of pins 122 and a partition 124 that partitions the plurality of pins 122 from one another. External terminals are coupled to the plurality of pins 122, and accordingly, a high-voltage power is provided to the converter 10, or a low-voltage power converted inside the converter 10 is provided to the external terminal, or a grounding structure of a ground region between the components inside the converter 10 and other components can be implemented.

In addition to this, the connector 120 may further include a signal terminal for transmitting and receiving electrical signals between the converter 10 and other components.

The converter 10 may include a refrigerant pipe 200. The refrigerant pipe 200 may be coupled to the housing 100. As an example, the housing 100 may include a heat dissipation area 130 to accommodate the refrigerant pipe 200, and the heat dissipation area 130 may have a shape being protruded outward from an outer surface of the housing 100. A space 132 in which the refrigerant pipe 200 is accommodated may be formed inside the heat dissipation area 130. Both ends of the heat dissipation area 130 may form a side surface of the housing 100. Specifically, the heat dissipation area 130 may be formed in the main body 102 among the housing 100. A region being protruded from a surface opposite to a surface the facing the cover 104 may be a heat dissipation area 130, and a space 132 in which a refrigerant pipe 200 is accommodated may be formed.

The refrigerant pipe 200 may have a pipe shape. The refrigerant pipe 200 may be made of a metal material. A flow path 202 may be formed inside the refrigerant pipe 200 to allow refrigerant to flow. The refrigerant pipe 200 may be disposed in the space 132 inside the heat dissipation area 130. Both ends of the refrigerant pipe 200 may be protruded outside the heat dissipation area 130. Both ends of the refrigerant pipe 200 may be protruded outward from a side surface of the housing 100. One end of the refrigerant pipe 200 is formed with a refrigerant inlet 210 providing refrigerant to the flow path 202, and a refrigerant outlet 220 may be formed at the other end of the refrigerant pipe 200 through which the refrigerant flowing along the flow path 202 is discharged to the outside. The refrigerant pipe 200 may be formed as a single line defined from the refrigerant inlet 210 to the refrigerant outlet 220. The refrigerant pipe 200 may have a region that is bent at least once or more.

A refrigerant supply unit that provides refrigerant to the flow path 202 may be coupled to the refrigerant inlet 210. A refrigerant recovery unit that recovers the refrigerant being discharged from the flow path 202 may be coupled to the refrigerant outlet 220.

The refrigerant pipe 200 may include a guide 250. The guide 250 may be provided in plural numbers and disposed in a region adjacent to the refrigerant inlet 210 and a region adjacent to the refrigerant outlet 220, respectively. The guide 250 may have a shape being protruded outward from an outer surface of the refrigerant pipe 200 so that its cross-sectional area is larger than that of other regions inside the refrigerant pipe 200. The cross-sectional shape of the guide 250 may be circular. When the plurality of guides 250 are respectively referred to as first guides and second guides, the first guide and the refrigerant inlet 210 and the second guide and the refrigerant outlet 220 may be spaced apart from each other by a predetermined distance. When the refrigerant pipe 200 is coupled inside the heat dissipation area 130, a side surface of the housing 100 and the guide 250 may be spaced apart by a predetermined distance.

Brackets 300 and 400 may be coupled to an outer surface of the refrigerant pipe 200. The brackets 300 and 400 may be coupled to an outer surface of the housing 100. The brackets 300 and 400 may be coupled to a side surface of the housing 100. The brackets 300 and 400 may be provided in plural numbers and may be respectively disposed at both end portions of the heat dissipation area 130. The brackets 300 and 400 may be disposed between an outer surface of the housing 100 and the guide 250. The surface facing an outer surface of the housing 100 is referred to as the inner surface of the brackets 300 and 400, and when a surface facing an inner surface and facing the guide 250 is referred to as an outer surface of the brackets 300 and 400, the inner surfaces of the brackets 300 and 400 may be in contact with the outer surfaces of the housing 100, and the outer surfaces of the brackets 300 and 400 may be in contact with the inner surfaces of the guide 250. Accordingly, the brackets 300 and 400 can be primarily coupled to an outer surface of the housing 100 through the guide 250.

The material of the brackets 300 and 400 may be plastic.

For convenience of explanation, in FIGS. 1 to 3, although it is illustrated that the bracket 300 according to a first embodiment is disposed at one end of the refrigerant pipe 200 adjacent to the refrigerant inlet 210, and the bracket 400 according to a second embodiment is disposed at the other end of the refrigerant pipe 200 adjacent to the refrigerant outlet 220, but either the bracket 300 according to a first embodiment or the bracket 400 according to a second embodiment can be selectively disposed, respectively, and this should also be understood as being included in the technical idea of the present invention. Likewise, the bracket 400 according to a second embodiment is disposed at one end of the refrigerant pipe 200 adjacent to the refrigerant inlet 210, and the bracket 300 according to a first embodiment may be disposed at the other end of the refrigerant pipe 200 adjacent to the refrigerant outlet 220.

Hereinafter, a bracket 300 according to a first embodiment will be described.

The bracket 300 may include a plurality of bodies. The bracket 300 may include a first body 310 and a second body 330. The first body 310 and the second body 330 may be hinge-coupled.

The first body 310 may comprise: a first body part 312 being coupled to an outer surface of the refrigerant pipe 200; a first coupling part 320 being disposed outside the first body part 312 and coupled to an outer surface of the housing 100; and a first hinge part 326 being disposed outside the first body part 312 and coupled to the second body 330.

The first body part 312 may have a cross section in the shape of an arc. The first body part 312 may have a semicircular cross section. The first body part 312 may have a shape being protruded outward from an outer surface of the first coupling part 320. An inner surface of the first body part 312 may be disposed to surround a portion of an outer surface of the refrigerant pipe 200.

A first protruding part 316 being protruded outward may be formed on an outer surface of the first body part 312. For an example, when viewed from the side surface of the converter 10, the first protruding part 316 may be disposed in a direction toward the 12 o'clock on an outer surface of the first body part 312. The first protruding part 316 is protruded more outward than other regions so that when the refrigerant supply unit is coupled to the refrigerant inlet 210 or the refrigerant recovery unit is coupled to the refrigerant outlet 220, it is possible to prevent the refrigerant supply unit or the refrigerant recovery unit from randomly rotating against the refrigerant inlet 210 or the refrigerant outlet 220. For an example, the refrigerant supply unit or the refrigerant recovery unit may include a groove into which the first protruding part 316 is coupled.

The first coupling part 320 may be coupled to a side surface of the housing 100. The first coupling part 320 may be disposed outside the first body part 312. The first coupling part 320 may be formed in a plate shape. The first coupling part 320 may be screw-coupled to a side surface of the housing 100. A hole 138 (see FIG. 3) into which the first coupling part 320 is screw-coupled may be formed on a side surface of the housing 100. In addition, in the first coupling part 320, a first hole 322 penetrating from an outer surface to an inner surface and facing the hole 138 may be formed. Therefore, when the bracket 300 is coupled to a side surface of the housing 100, the screw may penetrate through the first hole 322 and screw-coupled into the hole 138 of the housing 100.

Meanwhile, the first coupling part 320 may include a second hole 325 penetrating from one surface to the other surface. Additionally, a rib 137 being coupled to the second hole 325 may be formed on a side surface of the housing 100 facing the second hole 325. The cross-sectional area of the second hole 325 may be formed to be smaller than the cross-sectional area of the first hole 322.

The first hinge part 326 may be disposed outside the first body part 312. The first hinge part 326 may include a groove on a lower surface thereof to accommodate a portion of the second hinge part 346, which will be described later.

The second body 330 may comprise: a second body part 332 being coupled to an outer surface of the refrigerant pipe 200; a second coupling part 340 being disposed outside the second body part 332 and coupled to an outer surface of the housing 100; and a second hinge part 346 being disposed outside the second body part 332 and coupled to the first body 310.

The second body part 332 may have a cross section in the shape of an arc. The second body part 332 may have a semicircular cross section. The second body part 332 may have a shape being protruded outward from an outer surface of the second coupling part 340. An inner surface of the second body part 332 may be disposed to surround a portion of an outer surface of the refrigerant pipe 200.

The second body part 332 may be disposed at a lower portion of the first body part 312. The second body part 332 may be disposed to face the first body part 312 in an up and down direction. The refrigerant pipe 200 may be coupled to the inner space 302 (see FIG. 4) formed by coupling the first body part 312 and the second body part 332.

A second protruding part 336 being protruded outward may be formed on an outer surface of the second body part 332. For an example, when viewed from the side surface of the converter 10, the second protruding part 336 may be disposed in a direction toward the 6 o'clock on an outer surface of the second body part 332. The second protruding part 336 is protruded more outward than other regions so that when the refrigerant supply unit is coupled to the refrigerant inlet 210 or the refrigerant recovery unit is coupled to the refrigerant outlet 220, it is possible to prevent the refrigerant supply unit or the refrigerant recovery unit from randomly rotating against the refrigerant inlet 210 or the refrigerant outlet 220. For an example, the refrigerant supply unit or the refrigerant recovery unit may include a groove into which the second protruding part 336 is coupled.

The second coupling part 340 may be coupled to a side surface of the housing 100. The second coupling part 340 may be disposed outside the second body part 342. The second coupling part 340 may be formed in a plate shape. The second coupling part 340 may be screw-coupled to a side surface of the housing 100. A hole 138 (see FIG. 3) into which the second coupling part 340 is screw-coupled may be formed on a side surface of the housing 100. In addition, in the second coupling part 340, a third hole 342 penetrating from an outer surface to an inner surface and facing the hole 138 may be formed. Therefore, when the bracket 300 is coupled to a side surface of the housing 100, the screw may penetrate through the second hole 342 and screw-coupled into the hole 138 of the housing 100.

The second hinge part 346 may be disposed outside the second body part 332. The second hinge part 346 may be coupled to the first hinge part 326. The bracket 300 may include a hinge pin (not shown) having one end coupled to the first hinge part 326 and the other end coupled to the second hinge part 346. Accordingly, the first body 310 or the second body 330 may rotate about the hinge pin.

Specifically, as illustrated in FIG. 5(a), by the coupling of the rib 137 and the second hole 325, the second body 330 can rotate counterclockwise about the hinge pin in a state in which the first body 310 is primarily coupled to a side surface of the housing 100. At this time, as illustrated in FIG. 5(b), when the third hole 342 of the second coupling part 340 is disposed at a position facing the hole 138 formed on a side surface of the housing 100, the bracket 300 may be screw-coupled to a side surface of the housing 100 through a screw S.

According to the above structure, a structure that prevents the rotation of the refrigerant pipe is implemented using a bracket so that there is an advantage in that the coupling between a refrigerant pipe and other components can be maintained firmly in a region where refrigerant is supplied or recovered.

In addition, since a structure that prevents the rotation is implemented only with a bracket 300 regardless of the type of the refrigerant pipe 300, there is an advantage in that the degree of freedom in design can be increased. For example, in the present embodiment, the refrigerant pipe 300 in the shape of a single line pipe has been described as an example, but it is not limited thereto, and it may be a form in which a connection part such as a spigot being removably coupled to both ends of the pipe through which the refrigerant flows, or even in a form in which a bent type pipe being bent from both ends of the pipe through which the refrigerant flows is additionally provided, prevention of rotation between different configurations can be implemented through the bracket 300. In this case, the bracket 300 may be coupled to an outer surface of the spigot or an outer surface of the bent type pipe.

Hereinafter, the bracket 400 according to a second embodiment will be described.

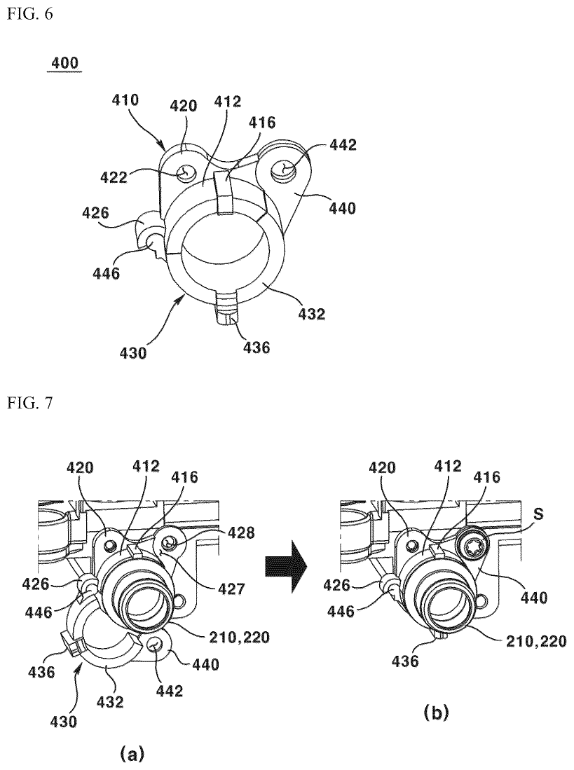

FIG. 6 is a perspective view of a bracket according to a second embodiment of the present invention; and FIG. 7 is a diagram for explaining the process of coupling a bracket and a refrigerant pipe according to a second embodiment of the present invention.

The present embodiment is the same as the first embodiment in other respects, but there are some differences in the coupling of the first body and the second body. Therefore, hereinafter, only the characteristic parts of the present embodiment will be described, and the description of the first embodiment will be cited for the remaining parts.

Referring to FIGS. 6 and 7, the bracket 400 may include a plurality of bodies. The bracket 400 may include a first body 410 and a second body 430. The first body 410 and the second body 430 may be hinge-coupled.

The first body 410 may comprise: a first body part 412 being coupled to an outer surface of the refrigerant pipe; a first coupling part 420 being disposed outside the first body part 412 and coupled to an outer surface of the housing 100; and a first hinge part 426 being disposed outside the first body part 412 and coupled to the second body 430.

The first body part 412 may have a cross section in the shape of an arc. The first body part 412 may have a shape being protruded outward from an outer surface of the first coupling part 420. An inner surface of the first body part 412 may be disposed to surround a portion of an outer surface of the refrigerant pipe.

A first protruding part 416 being protruded outward may be formed on an outer surface of the first body part 412. For an example, when viewed from the side surface of the converter, the first protruding part 416 may be disposed in a direction toward the 12 o'clock on an outer surface of the first body part 412. The first protruding part 416 is protruded more outward than other regions so that when the refrigerant supply unit is coupled to the refrigerant inlet or the refrigerant recovery unit is coupled to the refrigerant outlet, it is possible to prevent the refrigerant supply unit or the refrigerant recovery unit from randomly rotating against the refrigerant inlet or the refrigerant outlet. For an example, the refrigerant supply unit or the refrigerant recovery unit may include a groove into which the first protruding part 416 is coupled.

The first coupling part 420 may be coupled to a side surface of the housing. The first coupling part 420 may be disposed outside the first body part 412. The first coupling part 420 may be formed in a plate shape. The first coupling part 420 may be screw-coupled to a side surface of the housing. A hole 138 into which the first coupling part 420 is screw-coupled may be formed on a side surface of the housing. In addition, the first coupling part 420 may penetrate from an outer surface to an inner surface to form a first hole 428 facing the hole 138. Accordingly, when the bracket 400 is coupled to a side surface of the housing, the screw may penetrate through the first hole 428 and be screw-coupled into the hole 138 of the housing.

Meanwhile, the first coupling part 420 may include a second hole 422 penetrating from one surface to the other surface. Additionally, a rib 137 being coupled to the second hole 422 may be formed on a side surface of the housing facing the second hole 422. The cross-sectional area of the second hole 422 may be formed to be smaller than the cross-sectional area of the first hole 428.

The first coupling part 420 may include two or more regions with different thicknesses. The two or more regions may be disposed to be stepped from each other on an outer surface of the first coupling part 420. For example, a step region 427 (FIG. 7) may be formed on an outer surface of the first coupling part 420 in a shape that is recessed more inward than other regions. The thickness of the step region 427 may be smaller than the thickness of other regions of the first coupling part 420. The first hole 428 may be formed in the step region 427. The step region 427 may be disposed at one end of the first coupling part 420 with respect to a circumferential direction.

The first hinge part 426 may be disposed outside the first body part 412. The first hinge part 426 may include a groove on its lower surface to accommodate a portion of the second hinge part 446, which will be described later.

The second body 430 may comprise: a second body part 432 being coupled to an outer surface of the refrigerant pipe; a second coupling part 440 being disposed outside the second body part 432 and coupled to an outer surface of the step region 427; and a second hinge part 446 being disposed outside the second body part 432 and coupled to the first body 410.

The second body part 432 may have a cross section in the shape of an arc. The length of the second body part 432 in a circumferential direction may be formed to be longer than the circumferential length of the first body part 412 in a circumferential direction. The inner surface of the second body part 432 may be disposed to surround a portion of an outer surface of the refrigerant pipe.

The second body part 432 may be disposed at a lower portion of the first body part 412. The second body part 432 may be disposed in an up and down direction with the first body part 412. Both ends of the second body part 432 may be in contact with both ends of the first body part 412. The refrigerant pipe may be coupled to an inner space formed by the coupling of the first body part 412 and the second body part 432.

A second protruding part 436 being protruded outward may be formed on an outer surface of the second body part 432. For an example, when viewed from the side surface of the converter, the second protruding part 436 may be disposed in a direction toward the 6 o'clock on an outer surface of the second body part 432. The second protruding part 436 may be disposed symmetrically with the first protruding part 416 with respect to the refrigerant pipe. The second protruding part 436 is protruded more outward than other regions so that when the refrigerant supply unit is coupled to the refrigerant inlet or the refrigerant recovery unit is coupled to the refrigerant outlet, it is possible to prevent the refrigerant supply unit or the refrigerant recovery unit from randomly rotating against the refrigerant inlet or the refrigerant outlet. For an example, the refrigerant supply unit or the refrigerant recovery unit may include a groove into which the second protruding part 436 is coupled.

The second coupling part 440 may be coupled to an outer surface of the first coupling part 420. The second coupling part 440 may be disposed to be overlapped with the first coupling part 420. The second coupling part 440 may be coupled to an outer surface of the step region 427. When the second coupling part 440 and the first coupling part 420 are coupled, the outer surface of the second coupling part 440 may form the same plane as the other region of an outer surface of the first coupling part 420 excluding the step region 427.

The second coupling part 440 may be disposed outside the second body part 432. The second coupling part 440 may be screw-coupled to a side surface of the housing. A hole 138 into which the second coupling part 440 is screw-coupled may be formed on a side surface of the housing. In addition, the second coupling part 440 may penetrate through an inner surface from an outer surface to form a third hole 442 facing the hole 138 and the first hole 428 of the first coupling part 420. Therefore, when the bracket 400 is coupled to a side surface of the housing, the screw may penetrate through the third hole 442 and the first hole 428 to be screw-coupled into the hole 138 of the housing.

The second hinge part 446 may be disposed outside the second body part 432. The second hinge part 446 may be coupled to the first hinge part 426. The bracket 400 may include a hinge pin (not shown) having one end coupled to the first hinge part 426 and the other end coupled to the second hinge part 446. Accordingly, the first body 410 or the second body 430 may rotate about the hinge pin.

Specifically, as illustrated in FIG. 7(a), by the coupling of the rib 137 (see FIG. 3) and the second hole 422, the second body 430 can rotate counterclockwise about the hinge pin in a state in which the first body 310 is primarily coupled to a side surface of the housing 100. At this time, as illustrated in FIG. 7(b), when the third hole 442 of the second coupling part 440 is disposed at a position facing the first hole 428 of the first coupling part 420, the bracket 400 may be screw-coupled to a side surface of the housing through a screw S.

In the above description, it is described that all the components constituting the embodiments of the present invention are combined or operated in one, but the present invention is not necessarily limited to these embodiments. In other words, within the scope of the present invention, all of the components may be selectively operated in combination with one or more. In addition, the terms “comprise”, “include” or “having” described above mean that the corresponding component may be inherent unless specifically stated otherwise, and thus it should be construed that it does not exclude other components, but further include other components instead. All terms, including technical and scientific terms, have the same meaning as commonly understood by one of ordinary skill in the art unless otherwise defined. Terms used generally, such as terms defined in a dictionary, should be interpreted to coincide with the contextual meaning of the related art, and shall not be interpreted in an ideal or excessively formal sense unless explicitly defined in the present invention.

The above description is merely illustrative of the technical idea of the present invention, and those skilled in the art to which the present invention pertains may make various modifications and changes without departing from the essential characteristics of the present invention. Therefore, the embodiments disclosed in the present invention are not intended to limit the technical idea of the present invention but to describe the present invention, and the scope of the technical idea of the present invention is not limited by these embodiments. The protection scope of the present invention should be interpreted by the following claims, and all technical ideas within the equivalent scope should be interpreted as being included in the scope of the present invention.

1. A converter comprising:
a housing;
a refrigerant pipe coupled to the housing and having end portions protruded from an outer surface of the housing; and
a bracket coupled to an outer surface of the refrigerant pipe,
wherein the bracket includes:
a first body encompassing a portion of an outer surface of the refrigerant pipe; and
a second body hinge-coupled to the first body and encompassing the other portion of an outer surface of the refrigerant pipe, and
wherein the first body or the second body includes a protruding part protruded from an outer surface thereof.

2. The converter according to claim 1, wherein the first body includes:
a first body part, in a shape of an arc, coupled to an outer surface of the refrigerant pipe; and
a first coupling part disposed outside the first body part and coupled to an outer surface of the housing, and
wherein the protruding part is disposed on an outer surface of the first body portion.

3. The converter according to claim 2, wherein the second body includes:
a second body part, in a shape of an arc, coupled to an outer surface of the refrigerant pipe; and
a second coupling part disposed outside the second body part and coupled to an outer surface of the housing, and
wherein the protruding part is disposed on an outer surface of the first body part.

4. The converter according to claim 3, wherein the first body includes a first hinge part disposed outside the first body part,
wherein the second body includes a second hinge part disposed outside the second body part, and
wherein a hinge pin whose both ends are coupled to the first hinge part and the second hinge part is included.

5. The converter according to claim 3, wherein the protruding part includes:
a first protruding part disposed on an outer surface of the first body part; and
a second protruding part disposed on an outer surface of the second body part,
wherein the first protruding part and the second protruding part are disposed symmetrically about the refrigerant pipe.

6. The converter according to claim 3, wherein the first coupling part includes a first hole penetrating from an inner surface to an outer surface,
wherein the housing includes a first screw hole facing the first hole, and
wherein a screw penetrating the first hole and being coupled to the first screw hole is included.

7. The converter according to claim 6, wherein the first coupling part includes a second hole penetrating from an inner surface to an outer surface, and
wherein the housing includes a rib protruded from an outer surface and coupled to the second hole.

8. The converter according to claim 6, wherein the second coupling part includes a third hole penetrating from the inner surface to the outer surface,
wherein the housing includes a second screw hole facing the third hole, and
wherein a screw penetrating the third hole and coupled to the second screw hole is included.

9. The converter according to claim 6, wherein a step region is disposed on an outer surface of the first coupling part and has a concave shape,
wherein the second coupling part is coupled to the step region and includes a third hole facing the first hole, and
wherein the screw penetrates through the third hole and the first hole to be coupled to the first screw hole.

10. The converter according to claim 1, wherein the refrigerant pipe includes a guide formed to have a larger cross-sectional area than other regions, and
wherein the bracket is disposed between the guide and an outer surface of the housing.

11. The converter according to claim 1, wherein a material of the bracket is plastic, and
wherein a material of the refrigerant pipe is metal.

12. The converter according to claim 1, wherein an inner surface of the bracket is in contact with an outer surface of the housing, and
wherein an outer surface of the bracket is in contact with an inner surface of the guide.

13. The converter according to claim 1, wherein the housing includes a heat dissipation area within which the refrigerant pipe is accommodated, and
wherein both ends of the refrigerant pipe protrude outside the heat dissipation area.

14. The converter according to claim 7, wherein a cross-sectional area of the second hole is smaller than a cross-sectional area of the first hole.

15. The converter according to claim 9, wherein when the second coupling part is coupled to the step region, an outer surface of the first coupling part and an outer surface of the second coupling part form a same plane.

16. A converter comprising:
a housing;
a refrigerant pipe coupled to the housing and having end portions protruded from an outer surface of the housing; and
a bracket coupled to an outer surface of the refrigerant pipe,
wherein the bracket includes:
a first body encompassing a portion of an outer surface of the refrigerant pipe; and
a second body hinge-coupled to the first body and encompassing the other portion of an outer surface of the refrigerant pipe,
wherein the refrigerant pipe includes a guide formed to have a larger cross-sectional area than other regions, and
wherein the bracket is disposed between the guide and an outer surface of the housing.

17. The converter according to claim 16, wherein the first body includes:
a first body part, in a shape of an arc, coupled to an outer surface of the refrigerant pipe; and
a first coupling part disposed outside the first body part and coupled to an outer surface of the housing.

18. The converter according to claim 17, wherein the second body includes:
a second body part, in a shape of an arc, coupled to an outer surface of the refrigerant pipe; and
a second coupling part disposed outside the second body part and coupled to an outer surface of the housing.

19. The converter according to claim 18, wherein the first body includes a first hinge part disposed outside the first body part,
wherein the second body includes a second hinge part disposed outside the second body part, and
wherein a hinge pin whose both ends are coupled to the first hinge part and the second hinge part is included.

20. The converter according to claim 18, wherein the first coupling part includes a first hole penetrating from an inner surface to an outer surface,
wherein the housing includes a first screw hole facing the first hole, and
wherein a screw penetrating the first hole and being coupled to the first screw hole is included.
